(19) United States
(12) Patent Application Publication
(10) Pub. No.: US 2006/0169671 A1
(43) Pub. Date: Aug. 3, 2006

(54) Plasma etching apparatus and plasma etching method

(76) Inventors: Go Miya, Tokyo (JP); Junichi Tanaka, Tokyo (JP); Seiichiro Kanno, Tokyo (JP); Akitaka Makino, Hikari-shi (JP); Motohiko Yoshigai, Hikari-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/072,305

(22) Filed: Mar. 7, 2005

(30) Foreign Application Priority Data
Jan. 28, 2005 (JP) 2005-022113

(51) Int. Cl. C23F 1/00; H01L 21/306

(52) U.S. Cl. 216/67; 156/345.33; 156/345.34

(57) ABSTRACT

To provide a plasma etching apparatus that achieves a high in-plane uniformity of the CD shift.

A plasma etching apparatus includes: a process chamber 26 in which a plasma etching process is performed on a process target object 1;

A first gas supply source 100 for supplying a first process gas; a second gas supply source 110 for supplying a second process gas; a first gas introduction area 42-1 having a first gas introduction port for introducing the first process gas into the process chamber 26; a second gas introduction area 42-2 having a second gas introduction port 3 for introducing the second process gas into the process chamber 26; flow controllers 102, 113 for adjusting the flow rates of the process gasses; and a gas flow divider 120 for dividing the process gas into a plurality of gas flows, in which the first gas introduction port and the second gas introduction port are provided substantially in the same plane, and the first gas introduction area 42-1 and the second gas introduction area 42-2 are separated from each other.

The present application is based on and claims priority of Japanese patent applications No. 2005-022113 filed on Jan. 28, 2005, the entire contents of which are hereby incorporated by reference.

### BACKGROUND OF THE INVENTION

1. Field of the Invention

The present invention relates to a plasma etching apparatus that processes a semiconductor substrate, such as a semiconductor wafer, and a plasma etching method using the plasma etching apparatus.

2. Description of the Related Art

Conventionally, in processes of manufacturing a semiconductor chip, a plasma etching apparatus using a reactive plasma is used to process a semiconductor substrate, such as a semiconductor wafer.

Here, as an example of the plasma etching, an etching process for forming a polysilicon (poly-Si) gate electrode of a metal oxide semiconductor (MOS) transistor (referred to as a gate etching process, hereinafter) will be described with reference to FIG. 8. As shown in FIG. 8(a), a process target object 1 (sometimes referred to as a wafer, hereinafter) before etching comprises a silicon (Si) substrate 2, a silicon dioxide (SiO₂) film 3, a polysilicon film 4 and a photoresist mask 5 stacked in this order from the bottom. The gate etching process is a process of exposing the wafer 1 to a reactive plasma, thereby removing a part of the polysilicon film 4 that is not covered with the photoresist mask 5. By the gate etching process, a gate electrode 6 is formed as shown in FIG. 8(b). The gate width 8 of the gate electrode 6 has a great effect on the performance of an electronic device and, therefore, is strictly controlled as a critical dimension (CD). In addition, a value resulting from subtracting the gate width 8 after etching from the width 7 of the photoresist mask before etching is referred to as a CD shift, which is an important indicator of whether the gate etching process is successfully accomplished or not.

As an example, a conventional plasma etching apparatus that performs the gate etching process described above will be described with reference to FIG. 9. On a process chamber side wall 20, there are mounted a process chamber lid 22 and a shower head plate 24 having multiple small openings 34 formed therein for introducing a process gas, and in the resulting process chamber 26, a process-target-object holding table 28 is provided. A process gas 36 is introduced into a space 32 between the process chamber lid 22 and the shower head plate 24 through an introduction pipe 30 disposed in an upper part of the process chamber side wall 20. Then, the process gas 36 is introduced into the process chamber 26 through the multiple gas introduction openings 34 in the shower head plate 24 to produce a plasma 38. The plasma etching process is accomplished by exposing the process target object 1 to the plasma 38. The process gas 36 and a volatile product resulting from a reaction during the plasma etching process are exhausted through a discharge port 40. The discharge port 40 is connected to a vacuum pump (not shown in this drawing), which decompresses the internal pressure of the process chamber 26 to about 0.5 to 10 Pascal (Pa).

The plasma etching apparatus described above is used for gate etching. However, with the recent trend toward greater diameters of the process target object 1, the plasma etching apparatus has become unable to ensure an adequate in-plane uniformity of the etch rate over a wide area of the process target object 1 or an adequate in-plane uniformity of the gate width 8. At the same time, with the recent trend toward shrinking semiconductor design rule, requirements about dimension control of the gate width 8 have become severer.

Now, stickiness and deposition of a reaction product onto a side wall of the gate electrode, which affects the dimension of the gate width 8, will be described. Conventional gate etching processes use a plurality of kinds of gasses, such as chlorine (Cl₂), hydrogen bromide (HBr), and oxygen (O₂). During etching, these gasses are turned into plasma to form an etchant, which is used to etch the polysilicon film 4. In this process, ions or radicals of chlorine (Cl), bromine (Br) and oxygen (O), which are dissociated from chlorine (Cl₂), hydrogen bromide (HBr), and oxygen (O₂) contained in the process gas 36, react with silicon derived from the polysilicon film 4, thereby producing a reaction product. While a volatile reaction product is exhausted through the discharge port 40, some nonvolatile reaction product sticks to and is deposited on the polysilicon film 4 or the photoresist mask 5 during etching. The nonvolatile reaction product deposited on the side wall of the gate electrode 6 serves as a protective film for the side wall against etching by the radicals. Therefore, if a small amount of nonvolatile reaction product is deposited on the side wall of the gate electrode 6, the gate width 8 is likely to be narrow when the etching process is completed. On the other hand, if a large amount of nonvolatile reaction product is deposited on the wide wall of the gate electrode 6, the deposited nonvolatile reaction product serves as a mask against etching, and thus, the gate width 8 is likely to be wide when the etching process is completed.

As described above, the concentration of the reaction product greatly affects the gate width 8. The concentration of the reaction product in the vicinity of the surface of the process target object 1 may be nonuniform over the surface of the process target object 1. As a result, the CD shift may be nonuniform over the surface of the process target object 1. For example, the concentration of a silicon-based reaction product derived from the polysilicon film 4 is higher in a region where the etch rate is high than in a region where the etch rate is low. This may cause an in-plane nonuniformity of the CD shift.

In addition, while the central area of the process target object 1 has silicon to be etched in areas surrounding the area, the peripheral area of the process target object 1 has no silicon to be etched in areas surrounding the area. Therefore, even if the etch rate is uniform over the surface of the process target object 1, the concentration of the silicon-based reaction product derived from the polysilicon film 4 is higher in the central area than in the peripheral area. This may cause an in-plane nonuniformity of the CD shift.

Furthermore, reaction products that are easy to deposit include SiBrₓO_{y} (x, y=1, 2, 3) and SiClₓO_{y} (x, y=1, 2, 3), which are a compound of oxygen (O) and a silicon-bromine compound SiBrₓ (x=1, 2, 3) and a compound of oxygen (O) and a silicon-chlorine compound SiClₓ (x=1, 2, 3), respectively. If the oxygen concentration in the vicinity of the surface of the process target object 1 is nonuniform over the surface of the process target object 1, the amount of the silicon-based reaction product combined with oxygen, which is easy to deposit, is also nonuniform. Thus, a nonuniformity of the oxygen concentration may cause an in-plane nonuniformity of the CD shift.

In addition, if the in-plane uniformity of the etchant, such as radicals or ions of chlorine or bromine, in the vicinity of the surface of the process target object 1 is poor, the in-plane uniformity of the etch rate is also poor. Thus, a poor in-plane uniformity of the etchant may cause an in-plane nonuniformity of the CD shift.

As described above, a nonuniformity of the concentration of the reaction product, oxygen or the etchant over the surface of the process target object 1 may reduce the in-plane uniformity of the CD shift.

As described above, the conventional plasma etching apparatus shown in FIG. 9 tends to increase the reaction-product concentration in the central area of the process target object 1 and, therefore, has a problem that the gate width 8 tends to increase in the central area of the process target object 1.

As a technique for improving the in-plane uniformity of the concentration of such a silicon-based reaction product, there has been disclosed a technique of providing process gas introduction ports concentratedly in the vicinity of the central axis of the process chamber (see Japanese Patent Laid-Open No. 2002-100620, for example). This technique allows the process gas to be concentratedly introduced to the central area of the process target object to push the reaction product from the central area toward the peripheral area, thereby reducing the concentration of the reaction product in the central area. As a result, the in-plane uniformity of the concentration of the reaction product is improved, and the in-plane uniformity of the etch rate and CD shift is improved. However, if the flow rate of the introduced process gas is too greatly increased, there is a possibility that the concentration of the reaction product in the central area of the process target object may be reduced excessively and may be lower than the concentration in the peripheral area. In this case, the CD shift is greater in the central area of the process target object than in the peripheral area, so that the in-plane uniformity of the CD shift is degraded. Thus, there is a drawback that it is difficult to accomplish the etching process at a wide range of flow rates of the process gas.

Besides, to improve the in-plane uniformity of the concentration of the silicon-based reaction product, there has been proposed a technique that makes the concentration distribution of the reaction product in the vicinity of the surface of the process target object more uniform by providing an injector having two gas introduction ports, one of which faces to the central area of the process target object and the other of which faces to the circumference of the process chamber, and adjusting the flow rates of two process gasses introduced through the two gas introduction ports (see US Patent Application Publication No. 2003/0070620, for example). This technique overcomes the drawback of the technique disclosed in Japanese Patent Laid-Open No. 2002-100620 and is highly effective for making the concentration of the reaction product in the vicinity of the surface of the process target object for a wider range of flow rate of the process gas. However, the two process gases introduced to the central area of the process target object and to the circumference of the process chamber have the same composition, and therefore, it is difficult to control the concentration of the etchant or oxygen in the vicinity of the surface of the process target object.

Therefore, there is a possibility that the in-plane distribution of the etch rate or the CD shift cannot be controlled over an adequate area of the process target object. In addition, since the two gas introduction ports of the gas injector disposed in the middle of the upper part of the process chamber which face the central area of the process target object and the circumference of the process chamber are adjacent to each other, even if process gasses of different compositions are introduced through the introduction ports, the process gasses are mixed with each other before reaching the surface of the process target object, and thus, it is difficult to control the concentration of the etchant or oxygen in the vicinity of the surface of the process target object.

Furthermore, for improving the in-plane uniformity of ions or radicals in the plasma, there is proposed a technique of introducing a process gas at a plurality of sites in the process chamber. This technique relates to a reactive ion etching apparatus that has a flow controller that can independently control the flow rates of process gasses introduced into the process chamber through a plurality of introduction openings. This technique can change the in-plane uniformity of the etch rate. However, the process gasses introduced through the introduction openings have the same composition, and therefore, it is difficult to adjust the concentration of the etchant or oxygen in the vicinity of the surface of the process target object. Therefore, there is a possibility that the in-plane distribution of the etch rate or the CD shift cannot be controlled over an adequate area of the process target object.

As described above, both Japanese Patent Laid-Open No. 2002-100620 and US Patent Application Publication No. 2003/0070620 described above address only the control of the concentration distribution of the reaction product in the vicinity of the surface of the process target object. On the other hand, the inventors have proposed a technique of introducing gasses of different compositions through a plurality of gas introduction ports, taking into account not only the importance of the concentration distribution of the reaction product in the vicinity of the surface of the process target object but also the importance of controlling the compositions of the process gasses (see Japanese Patent Application No. 2003-206042). In this Japanese Patent Application No. 2003-206042, a specific structure of introducing a plurality of gasses using a shower head plate is not disclosed.

### SUMMARY OF THE INVENTION

In view of such circumstances, an object of the present invention is to provide a plasma etching apparatus and a plasma etching method that provide an excellent in-plane uniformity of the CD shift.

After due consideration, the inventors have achieved a specific structure. In the following, the structure will be described. In order to solve the problems with the prior art described above, a plasma etching apparatus according to the present invention comprises a plurality of gas supply units, flow controller units that adjust the flow rates a plurality of kinds of gasses, gas dividing means that divides a mixed gas into two gas flows in an arbitrary flow rate ratio, and a confluence section for introducing, at an arbitrary flow rate, another process gas to two gas pipes downstream of the gas dividing means, in which a first and a second process gas having passed through the confluence section are introduced to a process chamber. The first process gas and the second process gas pass through a first process gas introduction pipe and a second process gas introduction pipe, respectively, and then are introduced into a space between a process chamber lid and a shower head plate disposed facing an process target object. At the middle of the shower head plate, a central gas introduction area having a gas introduction opening (gas introduction port) is provided. Surrounding the central gas introduction area, an area having no gas introduction opening is provided, and surrounding the area, a peripheral gas introduction area having a gas introduction opening (gas introduction port) is provided. Furthermore, a protrusion is formed on an area of the process chamber lid facing the process chamber or on an area of the shower head plate, thereby forming a partition that prevents mixture of the first process gas and the second process gas.

Furthermore, according to the present invention, there are provided a plurality of first process gas introduction pipes and a plurality of second process gas introduction pipes for introducing the first and second process gasses into the space between the process chamber lid and the shower head plate.

Furthermore, according to the present invention, a second process chamber lid is provided between the first process chamber lid and the shower head plate. The first process gas is introduced through the first process gas introduction pipe into a space between the first process chamber lid and the second process chamber lid, passes through an opening formed in the middle of the second process chamber lid and then is introduced into the process chamber via the central gas introduction area. The second process gas is introduced through the second process gas introduction pipe into a space between the second process chamber lid and the shower head plate and then into the process chamber via the peripheral gas introduction area of the shower head plate.

Furthermore, according to the present invention, there is provided a plasma etching method using a plasma etching apparatus having: a process chamber in which a plasma etching is performed on a process target object; a first gas supply source that supplies a process gas; a second gas supply source provided separately from the first gas supply source; a first gas introduction port for introducing the process gas into the process chamber; a second gas introduction port provided separately from the first process gas introduction port; a flow controller that adjusts the flow rate of the process gas; and a gas flow divider that divides the process gas into a plurality of gas flows, in which the first gas introduction port and the second gas introduction port are provided substantially in the same plane, and process gasses supplied into the process chamber through the first gas introduction port and the second gas introduction port differ in flow rate or composition.

As described above, according to the present invention, there are provided a plasma etching apparatus and a plasma etching method that can achieve etching of a large-diameter process target object with a high in-plane uniformity.

### BRIEF DESCRIPTION OF THE DRAWINGS

FIG. 1 shows an arrangement of a gas supply system and a cross section of an ECR plasma etching apparatus according to a first embodiment of the present invention;

FIG. 2 is a top view of a shower head plate used in the first embodiment of the present invention;

FIG. 3(a) is an A-A cross sectional view of an upper part of a process chamber according to the first embodiment of the present invention, illustrating a positional relationship between a process chamber lid and a shower head plate;

FIG. 3(b) is a B-B vertical cross sectional view of the upper part of the process chamber according to the first embodiment of the present invention, illustrating a positional relationship between the process chamber lid and the shower head plate;

FIG. 4(a) is a table showing preset flow rates of process gasses used in the first embodiment of the present invention;

FIG. 4(b) is a table showing flow rates of the process gasses used in the first embodiment of the present invention;

FIG. 5(a) is a graph showing an oxygen concentration distribution that illustrates a comparison between a result obtained in the first embodiment of the present invention and a result obtained in a prior-art example;

FIG. 5(b) is a table showing values of the CD shift that illustrates a comparison between a result obtained in the first embodiment of the present invention and a result obtained in the prior-art example;

FIG. 6(a) is an A-A cross sectional view of an upper part of a process chamber according to a second embodiment of the present invention, illustrating a positional relationship between a process chamber lid and a shower head plate;

FIG. 6(b) is a B-B vertical cross sectional view of the upper part of the process chamber according to the second embodiment of the present invention, illustrating a positional relationship between the process chamber lid and the shower head plate;

FIG. 7(a) is an A-A cross sectional view of an upper part of a process chamber according to a third embodiment of the present invention, illustrating a positional relationship among a process chamber lid, a second process chamber lid and a shower head plate;

FIG. 7(b) is a B-B vertical cross sectional view of the upper part of the process chamber according to the third embodiment of the present invention, illustrating a positional relationship among the process chamber lid, the second process chamber lid and the shower head plate;

FIG. 8 consists of vertical cross sectional views of a process target object before and after gate etching; and

FIG. 9 is a vertical cross sectional view of a process chamber of a conventional plasma etching apparatus.

### DETAILED DESCRIPTION OF THE PREFERRED EMBODIMENTS

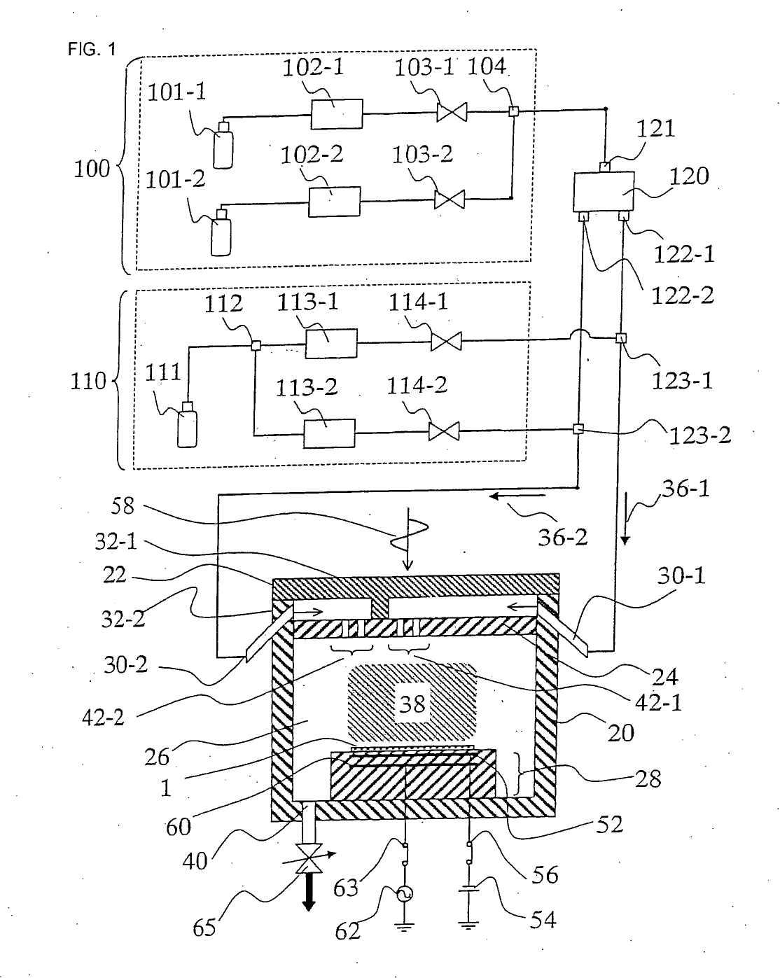

In the following, a first embodiment of the present invention will be described in detail with reference to FIGS. 1 to 5. First, with reference to FIG. 1, a microwave ECR plasma etching apparatus according to the first embodiment of the present invention and an arrangement of a gas system therefor will be described. According to the present invention, the gas supply system comprises a common gas subsystem (a first gas supply source) 100 and an additive gas subsystem (a second gas supply source) 110. The common gas subsystem 100 comprises gas supply means 101-1 and 101-2 as gas supply sources, flow controllers 102-1 and 102-2 for adjusting the flow rate of each gas, valves 103-1 and 103-2 for allowing or stopping the flow of each gas, and a confluence section 104 of the gasses in the common gas subsystem 100. In this embodiment, as common gasses, the gas supply means 101-1 supplies hydrogen bromide (HBr), and the gas supply means 101-2 supplies chlorine (Cl₂).

The common gasses join together at the confluence section 104, and the resulting gas is introduced into a gas flow divider 120 disposed downstream. The gas flow divider 120 is an apparatus capable of dividing any gas received at a gas-flow-divider inlet 121 among a plurality of gas-flow-divider outlets in an arbitrary flow rate ratio. Specifically, the gas flow divider 120 divides any process gas among two gas-flow-divider outlets, one of which has a flow meter that measures the flow rate of the process gas and a restrictor that limits or adjusts the flow of the process gas, and the other of which has a mass flow controller that allows process gas to flow at a preset flow rate. The flow meter transmits a preset flow-rate value to the mass flow controller, which allows the process gas flowing to the inlet to be divided between the two gas-flow-divider outlets in an arbitrary flow rate ratio.

In this embodiment, the gas flow divider 120 divides a mixture gas of hydrogen bromide and chlorine between the gas-flow-divider outlets 122-1 and 122-2 in a flow rate ratio of 8:2.

The additive gas subsystem 110 comprises gas supply means 111, a branch 112 for dividing a gas flow into a plurality of (two in this embodiment) gas flows, flow controllers 113-1 and 113-2 for adjusting the flow rate of the branched gas flow, and valves 114-1 and 114-2 for allowing and stopping the flow of the gas. In this embodiment, as the additive gas, the gas supply means supplies oxygen (O₂). The common gas (a mixture gas of hydrogen bromide and chlorine in this embodiment) leaving the gas-flow-divider outlet 122-1 joins with the additive gas (oxygen in this embodiment) having passed through the valve 114-1 at a confluence section 123-1, and the resulting mixture gas of the common gas and the additive gas (referred to as a first process gas 36-1 hereinafter) is guided to a first gas introduction pipe 30-1 disposed in a process chamber side wall 20.

Similarly, the common gas (a mixture gas of hydrogen bromide and chlorine in this embodiment) leaving the gas-flow-divider outlet 122-2 joins with the additive gas (oxygen in this embodiment) having passed through the valve 114-2 at a confluence section 123-2, and the resulting mixture gas of the common gas and the additive gas (referred to as a second process gas 36-2 hereinafter) is guided to a second gas introduction pipe 30-2 disposed in the process chamber side wall 20.

A process chamber lid 22 made of an insulator (quartz, in this embodiment) is mounted on the process chamber side wall 20 to form a process chamber 26, and a process-target-object holding table 28 is provided in the process chamber 26.

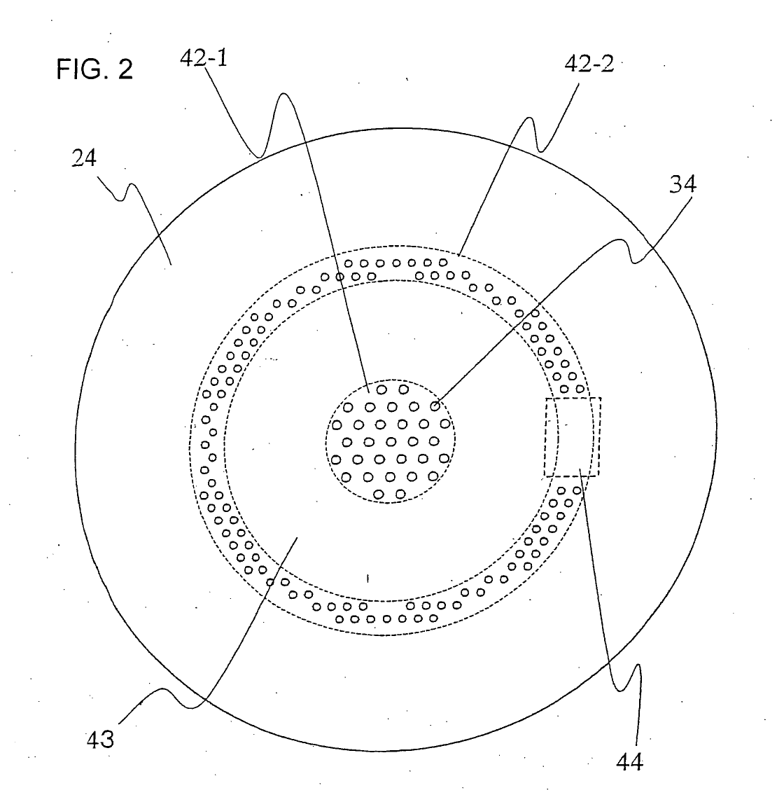

In FIGS. 1 and 2, the first process gas 36-1 is introduced through the first gas introduction pipe 30-1 into a central space 32-1 between the process chamber lid 22 and the shower head plate 24, which is made of an insulator, that is, quartz. The shower head plate 24 is disposed to face a process target object 1 and has, in the central area thereof, a central gas introduction area 42-1 in which a gas introduction opening (first gas introduction port) 34 is formed. The first process gas 36-1 is introduced into the process chamber 26 via the central gas introduction area 42-1. Similarly, the second process gas 36-2 is introduced through the second gas introduction pipe 30-2 into a space 32-2 between the process chamber lid 22 and the shower head plate 24. The shower head plate 24, which is disposed to face the process target object 1, has a peripheral gas introduction area 42-2 surrounding the central gas introduction area 42-1. The second process gas 36-2 is introduced into the process chamber 26 through a gas introduction opening (second gas introduction port) 34 formed in the peripheral gas introduction area 42-2. Here, the shower head plate has multiple gas introduction openings 34, and the diameters thereof are equal to or smaller than 1 mm.

In the process chamber 26, the process-target-object holding table 28 is provided, on which the process target object 1 is held. A suction electrode 52 is embedded in the process-target-object holding table 28. A direct-current power supply 54 connected to the suction electrode 52 causes an electrostatic force between the suction electrode 52 and the process target object 1, which makes the process target object 1 stick to the process-target-object holding table 28. In addition, a switch 56 is provided between the suction electrode 52 and the direct-current power supply 54 for turning on and off the application of the direct-current voltage.

On the process chamber lid 22, a magnetron that produces a microwave 58 is disposed (not shown). The microwave 58 produced by the magnetron is introduced into the process chamber 26 through the process chamber lid 22 and the shower head plate 24, which are made of an insulator (quartz, in this embodiment). In addition, a magnetic-field producing coil (not shown) is disposed around the process chamber side wall 20 and produces a magnetic field. A plasma 38 is produced by the electron cyclotron resonance (ECR) of the microwave 58 and the magnetic field.

The gate etching process is accomplished by exposing the process target object 1 to the plasma 38. A radio-frequency applying electrode 60 for applying a radio frequency voltage is embedded in the process-target-object holding table 28. A radio-frequency power supply 62 is connected to the radio-frequency applying electrode 60 and applies a radio frequency voltage to cause a bias potential, which makes ions in the plasma 38 be attracted to the process-target-object 1, thereby accomplishing anisotropic etching thereof. A switch 63 is provided between the radio-frequency applying electrode 60 and the radio-frequency power supply 62 for turning on and off the application of the radio frequency voltage.

The process gas 36 and a volatile substance resulting from a reaction during the plasma etching process are exhausted through a discharge port 40. The discharge port 40 is connected to a vacuum pump (not shown), which decompresses the internal pressure of the process chamber 26 to about 1 Pascal (Pa). In addition, a pressure control valve 65 is provided between the discharge port 40 and the vacuum pump. The internal pressure of the process chamber 26 is adjusted by adjusting the opening of the pressure control valve 65.

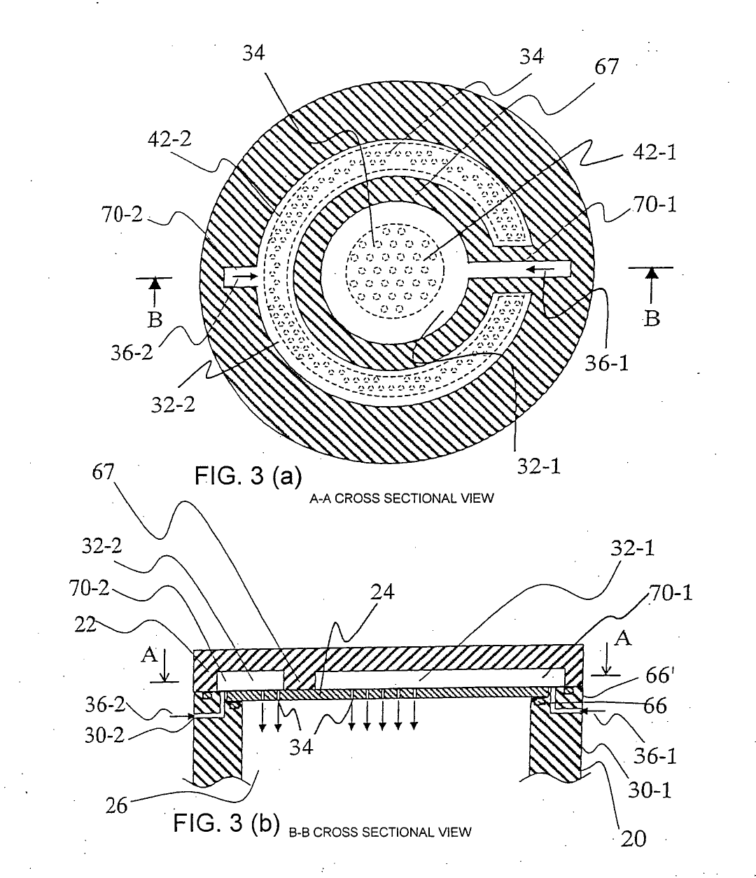

Now, structures of the process chamber lid 22 and the shower head plate 24 according to this embodiment will be described in detail with reference to FIGS. 2 and 3. FIG. 2 is an enlarged view of the shower head plate 24. As shown in this drawing, the shower head plate 24 has the central gas introduction area 42-1 near the center thereof, and the first process gas 36-1 is introduced in to the process chamber 26 through the gas introduction opening 34 formed in this area. In addition, there is an area 43 having no gas introduction opening 34 surrounding the central gas introduction area 42-1. In addition, surrounding the area 43, there is the peripheral gas introduction area 42-2, and the second process gas 36-2 is introduced into the process chamber 26 through the gas introduction opening 34 formed in this area. Here, the peripheral gas introduction area 42-2 has an area 44 in which no gas introduction opening 34 is formed. Therefore, in the peripheral gas introduction area 42-2, a plurality of gas introduction openings 34 are distributed in the shape of the letter C.

Now, a positional relationship between the process chamber lid 22 and the shower head plate 24 will be described with reference to FIG. 3. FIG. 3(a) is an A-A cross sectional view taken along the line A-A in a vertical cross sectional view (FIG. 3(b)), and FIG. 3(b) is a vertical cross sectional view taken along the line B-B in the A-A cross sectional view (FIG. 3(a)). Here, in order that the positional relationship between the process chamber lid 22 and the central gas introduction area 42-1, the peripheral gas introduction area 42-2 and the gas introduction openings 34 formed in the shower head plate 24 can be seen clearly, the central gas introduction area 42-1, the peripheral gas introduction area 42-2 and the gas introduction openings 34 are shown also in the A-A cross sectional view by the chain line.

As shown in the vertical cross sectional view (FIG. 3(b), the process chamber side wall 20 has two grooves formed in the top thereof, and O-rings 66 and 66′ are fitted into the grooves. The shower head plate 24 is mounted on the O-ring 66, and the process chamber lid 22 is mounted on the O-ring 66′. The O-ring 66′ and the process chamber lid 22 serve to keep the process chamber 26 hermetic.

In addition, a recess formed in the process chamber lid 22 and the shower head plate 24 form the central space 32-1 and the peripheral space 32-2. The first process gas 36-1 introduced through the first gas introduction pipe 30-1 is guided into the central space 32-1 through a first gas introduction path 70-1, and then guided into the process chamber 26 through the gas introduction openings 34 formed in the central gas introduction area 42-1. Similarly, the second process gas 36-2 introduced through the second gas introduction pipe 30-2 is guided into the peripheral space 32-2 through a second gas introduction path 70-2, and then guided into the process chamber 26 through the gas introduction openings 34 formed in the peripheral gas introduction area 42-2.

The central space 32-1 and the gas introduction path 70-1 are separated from the peripheral space 32-2 by a partition 67. During operation of the etching apparatus, the inside of the process chamber 26 is kept at a pressure lower than the atmospheric pressure. In addition, when the first process gas 36-1 and the second process gas 36-2 are introduced into the central space 32-1 and the peripheral space 32-2, respectively, at a normal flow rate for the plasma etching, the insides of the central space 32-1 and the peripheral space 32-2 are kept at a pressure (about 500 to 5000 Pa) lower than the atmospheric pressure. Therefore, the process chamber lid 22 is pressed from above by the atmospheric pressure, and the partition 67 is brought into intimate contact with the upper surface of the shower head plate 24. Thus, the first process gas 36-1 introduced to the central space 32-1 and the second process gas 36-2 introduced to the peripheral space 32-2 are adequately separated from each other and thus are not mixed with each other.

Using the arrangement described above, the process gasses 36-1 and 36-2 of different compositions can be introduced at different flow rates via the central gas introduction area 42-1 and the peripheral gas introduction area 42-2, respectively, formed in the shower head plate 24 made of quartz, and thus, the radical distribution or the like over the surface of the process target object 1 can be controlled.

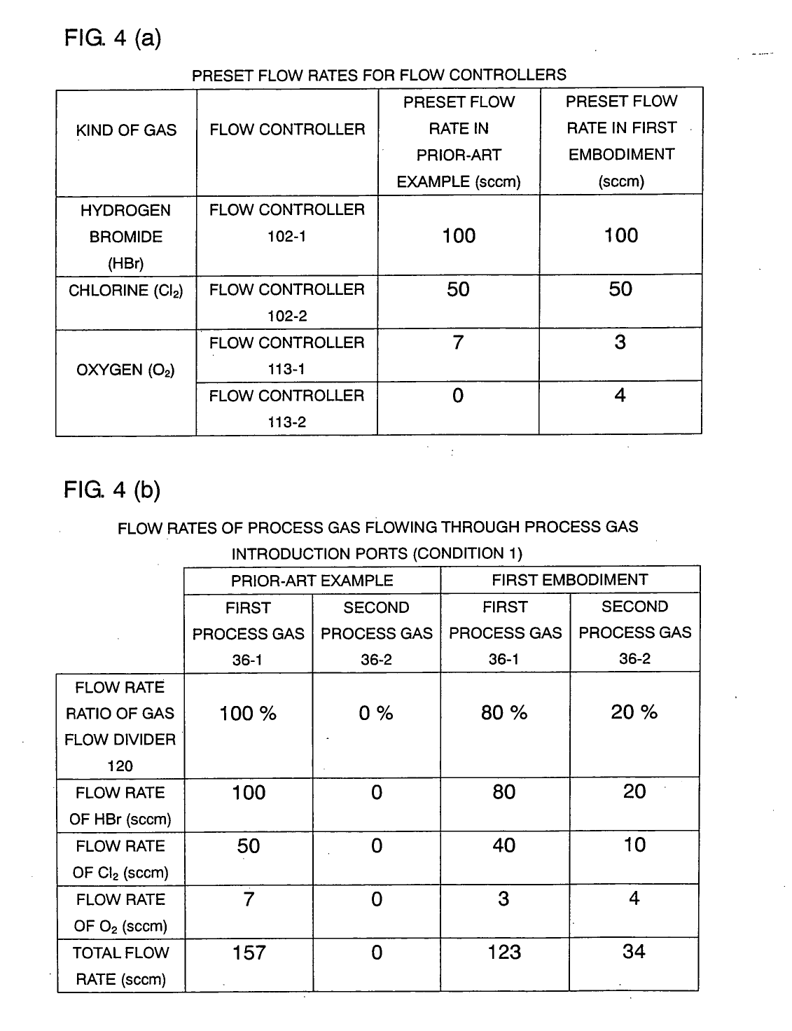

FIG. 4(a) is a table showing flow controllers for adjusting the flow rate of a process gas and preset flow rates thereof in a prior-art example and the first embodiment of the present invention, and FIG. 4(b) shows preset flow rate ratios of the gas flow divider 120 and flow rates of the first process gas 36-1 and the second process gas 36-2 in the prior-art example and the first embodiment of the present invention. In FIG. 4(b), in the case where the gas flow division ratio of the gas flow divider 120, that is, the ratio between the flow rates at the gas-flow-divider outlets 122-1 and 122-2 is 100:0, and the preset flow rate of the flow controller 113-2 is 0 sccm, the process gas is introduced only via the central gas introduction area 42-1 in the middle of the shower head plate 24. This is equivalent to a conventional process and, thus, is shown as a prior-art example.

Under the conditions according to this embodiment shown in FIG. 4, while the flow rate ratio among hydrogen bromide, chlorine and oxygen of the first process gas 36-1 is 80:40:3, the flow rate ratio among hydrogen bromide, chlorine and oxygen of the second process gas 36-2 is 80:40:16. In other words, in this embodiment, the second process gas 36-2 has a higher oxygen concentration than the first process gas 36-1.

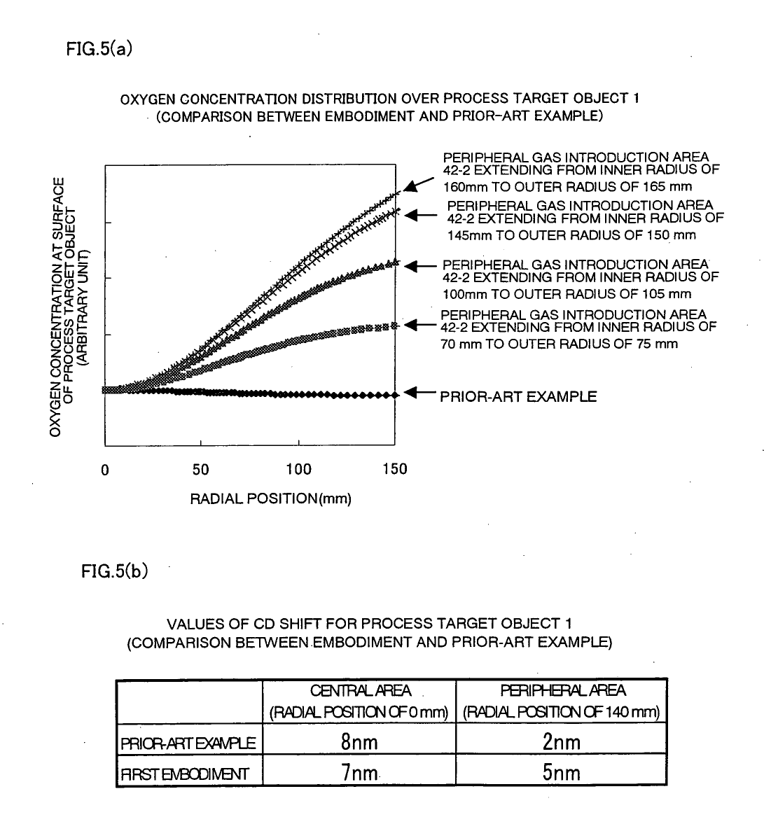

FIG. 5(a) shows a result of comparison of the oxygen concentration distribution over the surface of the process target object 1 between the prior-art example and this embodiment, obtained by fluid analysis conducted by the inventors. As for this embodiment, results for various radial positions of the peripheral gas introduction area 42-2 are also shown. The values of the oxygen concentration shown are those normalized with respect to the value at the center of the process target object 1. In this analysis, the central gas introduction area 42-1 extends from an inner radius of 0 mm to an outer radius of 20 mm, and the distance between the shower head plate 24 and the process target object 1 is 100 mm. In addition, the internal pressure of the process chamber 26 is 2 Pa.

In the prior-art example, since the process gas 36 is introduced only via the central gas introduction area, the pressure is lower in the peripheral area than in the central area of the process target object 1, and the oxygen concentration is lower than in the peripheral area than in the central area. To the contrary, as can be seen, in this embodiment, the oxygen concentration in the peripheral area can be increased. As described above, in the prior-art example, the concentration of the reaction product at the surface of the process target object 1 tends to be lower in the peripheral area than in the central area, so that the gate width 8 also tends to be narrower in the peripheral area than in the central area. To the contrary, according to this embodiment, since the oxygen concentration in the peripheral area of the process target object 1 is increased, the reaction product is easier to deposit in the peripheral area, and thus, the in-plane uniformity of the gate width 8 is improved.

FIG. 5(b) shows a result of measurement of the CD shift of the process target object 1. As shown in this drawing, the difference of CD shift between the central area and the peripheral area, which is large in the prior-art example, is small in this embodiment. Thus, it can be seen that, by introducing process gasses of different mixing ratios through a plurality of gas introduction pipes 30, the in-plane uniformity of the CD shift of the process target object 1 can be improved, and the gate etching can be achieved with a more uniform gate width 8.

Furthermore, as can be seen from the analysis result shown in FIG. 5(a), the outer the peripheral gas introduction area 42-2, the difference of oxygen concentration between the central area and the peripheral area of the process target object 1 can be increased, and thus, the range of control of the oxygen concentration distribution can be increased. This is because, if the central gas introduction area 42-1 and the peripheral gas introduction area 42-2 are positioned close to each other, the first process gas 36-1 and the second process gas 36-2 are likely to be mixed with each other before they reach the surface of the process target object 1. Therefore, in order to control the radical distribution over the surface of the process target object 1, it is effective to keep the central gas introduction area 42-1 and the peripheral gas introduction area 42-2 spaced apart from each other, and it is important to provide the area 43 having no gas introduction opening 34 between the central gas introduction area 42-1 and the peripheral gas introduction area 42-2.

In this embodiment, using the shower head plate 24 having the central gas introduction area 42-1, the peripheral gas introduction area 42-2 and the area 43 having no gas introduction opening 34 substantially in plane with each other, process gasses of different compositions can be introduced at different flow rates via the central gas introduction area 42-1 and the peripheral gas introduction area 42-2 with a simple arrangement, and the radical distribution over the surface of the process target object 1 can be controlled.

Furthermore, since the etching process uses a corrosive gas, such as hydrogen bromide and chlorine, the members to be in contact with the plasma 38 have to be made corrosion resistant. As described in this embodiment, it is desirable to use quartz as a material of the shower head plate 24.

Furthermore, in this embodiment, as shown in FIG. 1, the common gas (hydrogen bromide and chlorine in this embodiment), which is commonly introduced to a plurality of gas introduction pipes 30, is divided into gas flows in an arbitrary flow rate ratio by the gas flow divider 120, and the additive gases (oxygen in this embodiment) of different flow rates are introduced downstream of the gas-flow-divider outlets 122-1 and 122-2. Thus, process gasses of different mixing ratios can be introduced through a plurality of gas introduction pipes 30 with a simple arrangement.

While hydrogen bromide and chlorine are used as the common gas in this embodiment, the common gas is not limited thereto and may be another kind of gas.

In this embodiment, oxygen is used as the additive gas. This is intended to cause combination of oxygen and the reaction product, such as SiBrₓ (x=1, 2, 3) or SiClₓ (x=1, 2, 3), thereby producing SiBrₓO_{y} (x, y=1, 2, 3) or SiClₓO_{y} (x, y=1, 2, 3), which are easy to deposit, and making SiBrₓO_{y} or SiClₓO_{y} stick to or be deposited on the polysilicon film 4 or the photoresist mask 5 for increasing the gate width 8. However, the additive gas is not limited to oxygen and may be another gas that can produce a reaction product that is easy to deposit. Alternatively, a gas that inhibits production of a reaction product that is easy to deposit may be used as the additive gas, and the concentration thereof may be adjusted over the surface of the process target object 1, thereby improving the in-plane uniformity of the gate width 8.

In this embodiment, the gas flow division ratio of the gas flow divider 120, that is, the ratio between the flow rates at the gas-flow-divider outlets 122-1 and 122-2 is 80:20. However, the ratio is not limited thereto. As described above, the concentration of the reaction product at the surface of the process target object 1 tends to be higher in the central area than in the peripheral area. Therefore, the uniformity of the concentration of the reaction product over the process target object 1 has to be improved by introducing the process gas at a higher flow rate in the central gas introduction area 42-1 than in the peripheral gas introduction area 42-2 to push the reaction product from the central area of the process target object 1 toward the peripheral area. Therefore, if the concentration of the reaction product is still higher in the central area of the process target object 1 than in the peripheral area even though the gas flow division ratio of the gas flow divider 120 is 80:20, the gas flow division ratio of the gas flow divider 120 may be changed (to 90:10, for example) to increase the flow rate of the first process gas 36-1, thereby improving the uniformity of the concentration of the reaction product over the process target object 1. In this case, the compositions of the first process gas 36-1 and the second process gas 36-2 (the proportions of oxygen in the first process gas 36-1 and the second process gas 36-2 in this embodiment) have to be adjusted by the flow controllers 113-1 and 113-2 controlling the flow rate of oxygen.

As described above, since the gas flow division ratio of the gas flow divider 120 and the preset flow rates of the flow controllers 113-1 and 113-2 are independently controlled, the concentration distribution of the reaction product and the concentration distribution of the radical (oxygen, for example) can be independently controlled over the surface of the process target object 1, and thus, the in-plane uniformity of the CD shift for the process target object 1 is improved.

Furthermore, in this embodiment two kinds of gasses, that is, hydrogen bromide and chlorine, are used as the common gas. However, the common gas is not limited thereto. According to the present invention, one kind or three or more kinds of gasses may be used as the common gas.

Furthermore, in this embodiment, oxygen is solely used as the additive gas. However, the additive gas is not limited to one kind of gas, and a plurality of kinds of gasses may be used as the additive gas.

Furthermore, while the proportion of oxygen in the second process gas 36-2 is higher than the proportion of oxygen in the first process gas 36-1 in this embodiment, the present invention is not limited thereto. For example, if the CD shift for the process target object 1 is greater in the peripheral area than in the central area, the proportion of oxygen in the second process gas 36-2 can be lower than the proportion of oxygen in the first process gas 36-1 to improve the in-plane uniformity of the CD shift.

Furthermore, in this embodiment, as the gas flow divider 120 for dividing the process gas into a plurality of gas flows, various gas flow dividers having various structures may be used.

In addition, a groove may be formed in the partition 67, and an O-ring be fitted into the groove to improve the sealing of the partition 67. In this case, the width of the partition 67 can be reduced. However, since the process chamber lid 22 and the shower head plate 24 are heated by the plasma 38 produced in the process chamber 26, it is desirable that the O-ring used is heat resistant. In addition, since the corrosive gases, such as chlorine and hydrogen bromide, are introduced to the central space 32-1 and the peripheral space 32-2, it is desirable that the O-ring used is not only heat resistant but also corrosion resistant.

In addition, in the case where the distance between the shower head plate 24 and the process target object 1 is small, for example, in the case where the distance between the shower head plate 24 and the process target object 1 is 100 mm or less, there is a possibility that the etch rate of the process target object 1 or the CD shift of the polysilicon gate in the area directly below the area 44 having no gas introduction opening 34 may be different from the etch rate or the CD shift in the other area. In this case, such a nonuniformity can be avoided by adopting an arrangement in which the peripheral gas introduction area 42-2 does not have the area 44 having no gas introduction opening 34 as described later.

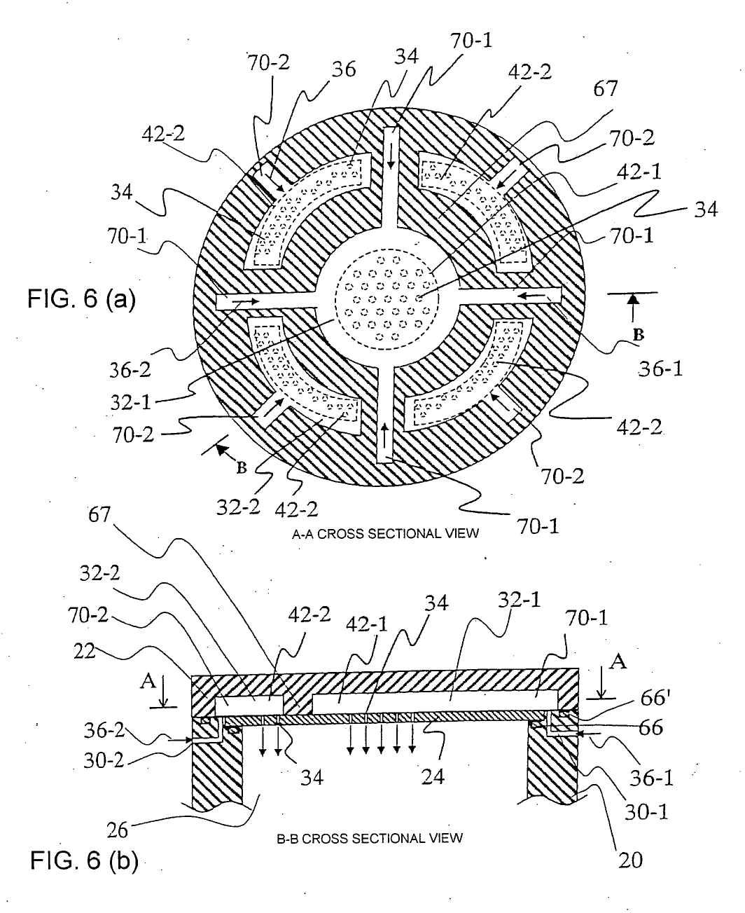

Now, a second embodiment of the present invention will be described with reference to FIG. 6. FIG. 6(a) is an A-A cross sectional view taken along the line A-A in a vertical cross sectional view (FIG. 6(b)), and FIG. 6(b) is a vertical cross sectional view illustrating a positional relationship between a process chamber lid 22 made of quartz and a shower head plate 24 made of quartz, taken along the line B-B in the A-A cross sectional view (FIG. 6(a)). In this drawing, as with FIG. 3, in order that the positional relationship between the process chamber lid 22 and a central gas introduction area 42-1, a peripheral gas introduction area 42-2 and gas introduction openings 34 formed in the shower head plate 24 can be seen clearly, the central gas introduction area 42-1, the peripheral gas introduction area 42-2 and the gas introduction openings 34 are shown also in the A-A cross sectional view by the chain line. In this embodiment, the same gas system as in the first embodiment is used for introducing the process gas to a process chamber 26.

In the first embodiment, one first gas introduction path 70-1 and one second gas introduction path 70-2 are provided. To the contrary, in this embodiment, four first gas introduction paths 70-1 at an angle of 90 degrees with each other and four second gas introduction paths 70-2 at an angle of 90 degrees with each other are provided. As in the first embodiment, the shower head plate 24 has the central gas introduction area 42-1 in the vicinity of the center, and a first process gas 36-1 is introduced into the process chamber 26 through the gas introduction opening 34 formed in this area. In addition, surrounding the central gas introduction area 42-1, there is an area having no gas introduction opening 34. Furthermore, surrounding this area, the peripheral gas introduction area 42-2 is formed, and a second process gas 36-2 is introduced into the process chamber 26 through a gas introduction opening 34 formed in this area.

As shown in the vertical cross sectional view (FIG. 6(b)), a recess formed in the process chamber lid 22 and the shower head plate 24 form a central space 32-1 and a peripheral space 32-2. The first process gas 36-1 introduced through a first gas introduction pipe 30-1 is guided into the central space 32-1 through the four first gas introduction paths 70-1, and then guided into the process chamber 26 through the gas introduction opening 34 formed in the central gas introduction area 42-1 of the shower head plate 24. Similarly, the second process gas 36-2 introduced through a second gas introduction pipe 30-2 is guided into the peripheral space 32-2 through the four second gas introduction paths 70-2, and then guided into the process chamber 26 through the gas introduction opening 34 formed in the peripheral gas introduction area 42-2 of the shower head plate 24.

The central space 32-1 and the gas introduction path 70-1 are separated from the peripheral space 32-2 by a partition 67. During operation of the etching apparatus, the inside of the process chamber 26 is kept at a pressure lower than the atmospheric pressure. In addition, when the first process gas 36-1 and the second process gas 36-2 are introduced into the central space 32-1 and the peripheral space 32-2, respectively, at a normal flow rate for the plasma etching, the insides of the central space 32-1 and the peripheral space 32-2 are kept at a pressure lower than the atmospheric pressure. Therefore, the process chamber lid 22 is pressed from above by the atmospheric pressure, and the partition 67 is brought into intimate contact with the upper surface of the shower head plate 24. Thus, the first process gas 36-1 introduced to the central space 32-1 and the second process gas 36-2 introduced to the peripheral space 32-2 are adequately separated from each other and thus are not mixed with each other.

Using the arrangement described above, the process gasses 36-1 and 36-2 of different compositions can be introduced at different flow rates via the central gas introduction area 42-1 and the peripheral gas introduction area 42-2, respectively, formed in the shower head plate 24 made of quartz. In addition, since the same gas supply system as in the first embodiment is used, as in the first embodiment, process gasses of different compositions can be introduced at different flow rates via the central gas introduction area 42-1 and the peripheral gas introduction area 42-2. Thus, the concentration distribution of the reaction product and the concentration distribution of the radical (oxygen, for example) can be independently controlled over the surface of the process target object 1, and thus, the in-plane uniformity of the CD shift for the process target object 1 is improved.

Furthermore, while one first gas introduction path 70-1 and one second gas introduction path 70-2 are provided in the first embodiment, four first gas introduction paths 70-1 at an angle of 90 degrees with each other and four second gas introduction paths 70-2 at an angle of 90 degrees with each other are provided in this embodiment. This is advantageous in that the process chamber lid 22 and the shower head plate 24 can be readily installed in the maintenance of the plasma etching apparatus.

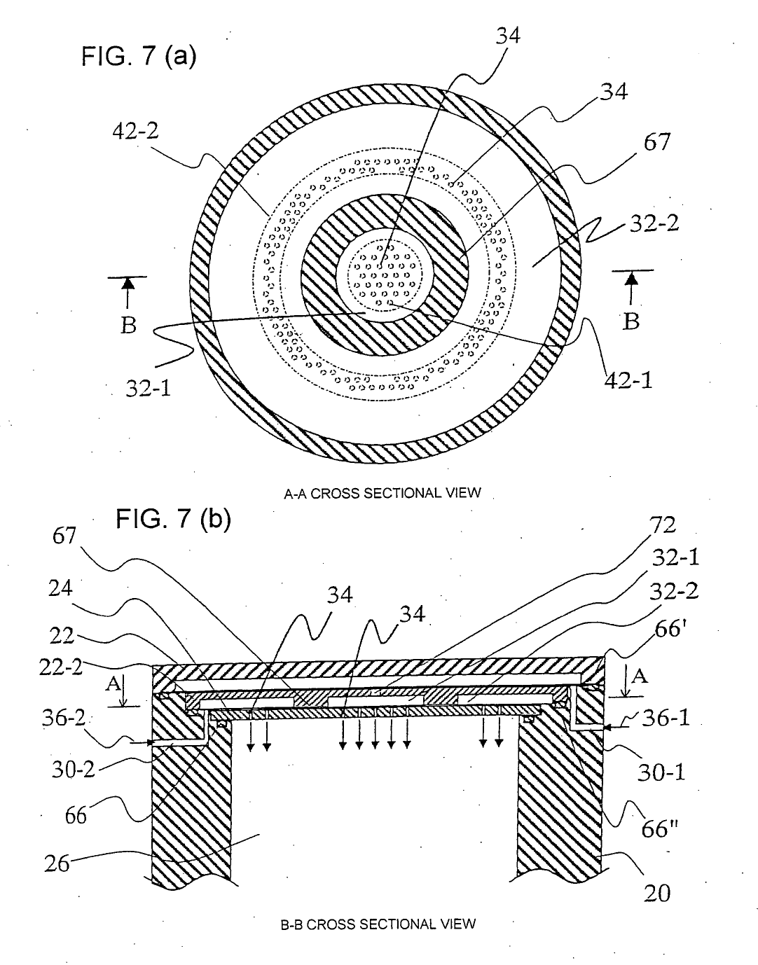

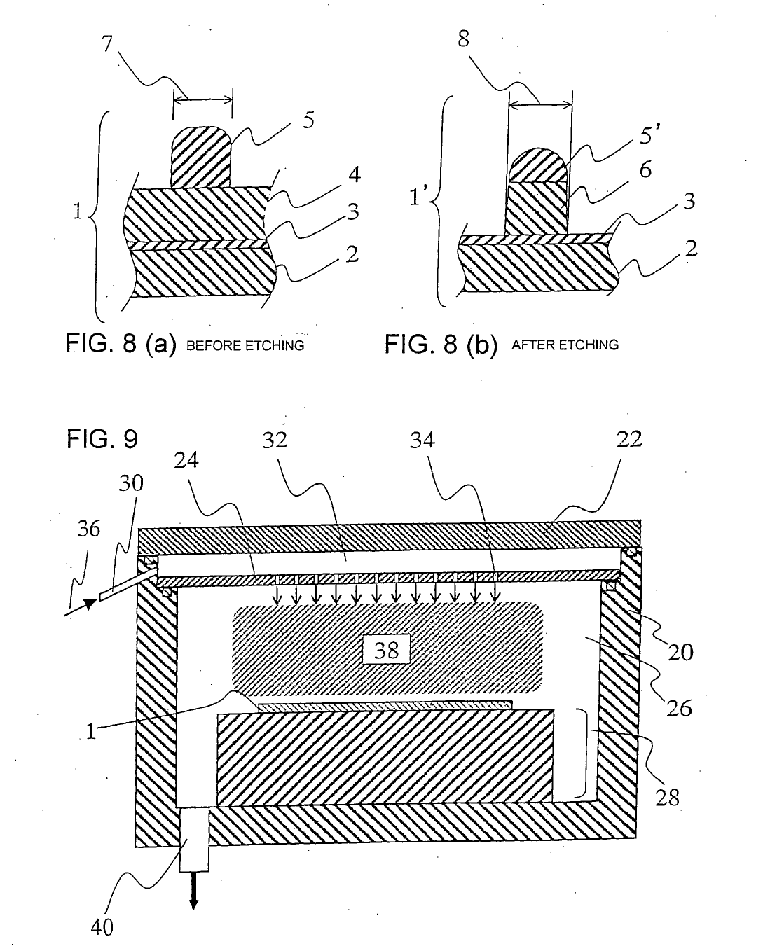

Now, a third embodiment of the present invention will be described. According to this embodiment, a disk-like second process chamber lid 22-2 is additionally provided between a process chamber lid 22 and a shower head plate 24 that are similar to those in the first embodiment described above. In the following, the third embodiment will be described with reference to FIG. 7. This drawing comprises a vertical cross sectional view (FIG. 7(b)) illustrating a positional relationship among the process chamber lid 22 made of quartz, the shower head plate 24 made of quartz, the second process chamber lid 22-2 made of quartz and a process chamber side wall 20 and an A-A cross sectional view (FIG. 7(a)) taken along the line A-A in the vertical cross sectional view. In order that the positional relationship between the second process chamber lid 22-2 and gas introduction openings 34 formed in the shower head plate 24 can be clearly seen, a central gas introduction area 42-1, a peripheral gas introduction area 42-2 and the gas introduction openings 34 are shown also in the A-A cross sectional view by the chain line, as with FIGS. 3 and 6.

The gas system for introducing the process gas to a process chamber 26 used in this embodiment is the same as that described in the first embodiment.

As in the first embodiment, the shower head plate 24 has the central gas introduction area 42-1 in the vicinity of the center, and a first process gas 36-2 is introduced into the process chamber 26 through a gas introduction opening 34 formed in this area. In addition, surrounding the central gas introduction area 42-1, there is an area having no gas introduction opening 34. Furthermore, surrounding this area, the peripheral gas introduction area 42-2 is formed, and a second process gas 36-2 is introduced into the process chamber 26 through a gas introduction opening 34 formed in this area. In addition, the second process chamber lid 22-2 has a recess and a partition 67, and a first process gas introduction hole 72 is formed in the middle of the second process chamber lid 22-2.

As shown in the vertical cross sectional view, the recess formed in the second process chamber lid 22-2 and the shower head plate 24 form a central space 32-1 and a peripheral space 32-2. The first process gas 36-1 introduced through a first gas introduction pipe 30-1 passes through a space defined by a recess formed in the process chamber lid (first process chamber lid) 22 and the second process chamber lid 22-2, is guided into the central space 32-1 formed between the central area of the second process chamber lid 22 and the shower head plate 24 through the first process gas introduction hole 72, and then guided into the process chamber 26 through the gas introduction opening 34 formed in the central gas introduction area 42-1 of the shower head plate 24.

The second process gas 36-2 introduced through a second gas introduction pipe 30-2 is guided into the peripheral space 32-2 formed between the peripheral area of the second process chamber lid 22-2 and the peripheral area of the shower head plate 24 and then guided into the process chamber 26 through the gas introduction opening 34 formed in the peripheral gas introduction area 42-2 of the shower head plate 24.

The central space 32-1 and the peripheral space 32-2 are separated from each other by the partition 67, which is formed by a protrusion on the second process chamber lid 22-2. During operation of the etching apparatus, the inside of the process chamber 26 is kept at a pressure lower than the atmospheric pressure. In addition, when the first process gas 36-1 and the second process gas 36-2 are introduced into the central space 32-1 and the peripheral space 32-2, respectively, at a normal flow rate for the plasma etching, the inside of the space between the process chamber lid 22 and the second process chamber lid 22-2 is kept at a pressure (about 500 to 5000 Pa) lower than the atmospheric pressure. Therefore, the process chamber lid 22 is pressed from above by the atmospheric pressure, and the second process chamber lid 22-2 is pressed downwardly by a protrusion (not shown) formed on a part of the recess of the process chamber lid 22. Thus, the partition 67 formed on the second process chamber lid 22-2 is brought into intimate contact with the upper surface of the shower head plate 24. Thus, the first process gas 36-1 introduced to the central space 32-1 and the second process gas 36-2 introduced to the peripheral space 32-2 are adequately separated from each other and thus are not mixed with each other.

Using the arrangement described above, the process gasses 36-1 and 36-2 of different compositions can be introduced at different flow rates via the central gas introduction area 42-1 and the peripheral gas introduction area 42-2, respectively, formed in the shower head plate 24 made of quartz. In addition, since the same gas system as in the first embodiment is used, as in the first embodiment, process gasses of different compositions can be introduced at different flow rates via the central gas introduction area 42-1 and the peripheral gas introduction area 42-2. Thus, the concentration distribution of the reaction product and the concentration distribution of the radical (oxygen, for example) can be independently controlled over the surface of the process target object 1, and thus, the in-plane uniformity of the CD shift for the process target object 1 is improved.

Furthermore, while the peripheral gas introduction area 42-2 in the shower head plate 24 has the area 44 having no introduction opening 34 in the first and second embodiments, introduction openings 34 can be formed along the whole circumference of the peripheral gas introduction area 42-2 in this embodiment. Therefore, even if the distance between the shower head plate 24 and the process target object 1 is narrow, there is no possibility that the circumferential uniformity of the etch rate of the process target object 1 or the CD shift of the polysilicon gate in the plasma etching may be degraded.

In the first to third embodiments, the partition 67 exerts a force on the shower head plate 24 made of quartz as described above. The fracture of brittle materials, such as quartz, can be evaluated in terms of tensile stress. Considering the tensile stress of 50 MPa and the safety factor (of 20, for example) of quartz, in order to avoid fracture of the shower head plate 24 made of quartz, it is desirable the tensile stress on the shower head plate 24 is 2.5 MPa or less.

In addition, in the first and second embodiments of the present invention, the partition 67 is formed by a protrusion formed on the lower surface of the process chamber lid 22. However, the present invention is not limited thereto. For example, the partition 67 may be formed by a protrusion on the upper surface of the shower head plate 24 and be brought into intimate contact with the lower surface of the process chamber lid 22 to separate the central space 32-1 and the peripheral space 32-2 from each other. However, since the shower head plate 24 is in direct contact with the plasma 38, the shower head plate 24 is worn in the course of the etching process and has to be replaced with a new one. Therefore, it is essential that the shower head plate 24 can be manufactured at a low cost, and it is desirable that the shower head plate 24 has a simple structure. For this reason, the protrusion forming the partition 67 is desirably formed on the process chamber lid 22, rather than on the shower head plate 24. Similarly, in the third embodiment, while a protrusion can be formed on the shower head plate 24 to form the partition 67, the partition 67 is desirably formed on the second process chamber lid 22-2.

In addition, if the partition 67 is too narrow, the sealing is degraded, and there is a possibility that the first process gas 36-1 may leak from the central space 32-1 to the peripheral space 32-2, or the second process gas 36-2 may leak from the peripheral space 32-2 to the central space 32-1. The probability of the leakage is high when the internal pressure of one of the spaces (that is, the central space 32-1 or the peripheral space 32-2) is as low as that of the process chamber 26 and the internal pressure of the other space is high. In general, considering the flow rate of the first process gas 36-1 or the second process gas 36-2 used for the etching, the internal pressure of the central space 32-1 or the peripheral space 32-2 is about 500 to 5000 Pa. Therefore, considering the conductance of the partition, the width of the partition 67 is desirably 100 mm or more. In addition, in the first to third embodiments, the microwave 58 is used as means for producing an electric field for producing a plasma. However, the present invention is not limited thereto. For example, an antenna may be installed on the process chamber lid 22 made of an insulating material, and a radio frequency within the ultra radio frequency (UHF) band may be applied to the antenna to produce the plasma 38. Alternatively, a coil is installed on the process chamber lid 22 made of an insulating material, and a radio frequency may be applied to the coil to produce the plasma 38 by inductive coupling.

While embodiments of the present invention have been described taking the gate etching as an example, the application of the present invention is not limited to the gate etching. Of course, the present invention can be applied to plasma etching apparatus and plasma etching methods used for metals, such as aluminum (Al), silicon dioxide (SiO₂), or ferroelectric materials.

What is claimed is:

1. A plasma etching apparatus, comprising:
a process chamber in which a plasma etching is performed on a process target object;
a first gas supply source that supplies a first process gas;
a second gas supply source provided separately from said first gas supply source that supplies a second process gas;
a first gas introduction port for introducing the first and the second process gas into said process chamber;
a second gas introduction port for introducing the first and the second process gas into said process chamber provided separately from said first process gas introduction port;
a flow controller that adjusts the flow rate of the first process gas and a flow controller that adjusts the flow rate of the second process gas;
a gas flow divider that divides the first process gas into a plurality of gas flows; and
a confluence section for a second process gas to join with the divided first process gas, respectively,
wherein said first gas introduction port and said second gas introduction port are provided substantially in the same plane and located so as to face said process target object.

2. The plasma etching apparatus according to claim 1, wherein said first gas introduction port and said second gas introduction port are provided substantially in the same plane, and an area having no gas introduction port is provided between said first gas introduction port and said second gas introduction port.

3. The plasma etching apparatus according to claim 1, further comprising:
a process chamber lid mounted on the top of said process chamber;
a disk having said first gas introduction port and said second gas introduction port formed therein and disposed below said process chamber lid;
a first space provided between said process chamber lid and said disk for introducing a first process gas to said process chamber through said first gas introduction port; and
a second space provided between said process chamber lid and said disk for introducing a second process gas to said process chamber through said second gas introduction port,
wherein said first space and said second space are separated from each other by a protrusion formed on one of said process chamber lid and said disk being brought into intimate contact with the other.

4. The plasma etching apparatus according to claim 1, further comprising:
a process chamber lid mounted on the top of said process chamber;
a disk having said first gas introduction port and said second gas introduction port formed therein and disposed below said process chamber lid;
a first space provided between said process chamber lid and said disk for introducing a first process gas to said process chamber through said first gas introduction port; and
a second space provided between said process chamber lid and said disk for introducing a second process gas to said process chamber through said second gas introduction port,
wherein said first space and said second space are separated from each other by a protrusion formed on one of said process chamber lid and said disk being brought into intimate contact with the other, and at least one of said process chamber lid and said disk is made of quartz glass.

5. The plasma etching apparatus according to claim 1, comprising:
a process chamber lid mounted on the top of said process chamber;
a second process chamber lid having an opening and disposed below said process chamber lid;
a disk having said first gas introduction port and said second gas introduction port formed therein and disposed below said second process chamber lid;
a first space provided between said second process chamber lid and said disk for introducing a first process gas to said process chamber through said first gas introduction port; and
a second space provided between said second process chamber lid and said disk for introducing a second process gas to said process chamber through said second gas introduction port,
wherein said first space and said second space are separated from each other by a protrusion formed on one of said second process chamber lid and said disk being brought into intimate contact with the other.

6. The plasma etching apparatus according to claim 1, comprising:
a process chamber lid mounted on the top of said process chamber;
a second process chamber lid having an opening and disposed below said process chamber lid;
a disk having said first gas introduction port and said second gas introduction port formed therein and disposed below said second process chamber lid;
a first space provided between said second process chamber lid and said disk for introducing a first process gas to said process chamber through said first gas introduction port; and
a second space provided between said second process chamber lid and said disk for introducing a second process gas to said process chamber through said second gas introduction port,
wherein said first space and said second space are separated from each other by a protrusion formed on one of said second process chamber lid and said disk being brought into intimate contact with the other, and at least one of said process chamber lid, said second process chamber lid and said disk is made of quartz glass.

7. The plasma etching apparatus according to claim 1, wherein gasses introduced through said first gas introduction port and said second gas introduction port differ from each other in composition or flow rate.

8. The plasma etching apparatus, comprising:
a process chamber in which a plasma etching is performed on a process target object;
a first process gas supply source;
a second process gas supply source;
a first gas introduction port for introducing a process gas into said process chamber;
a second gas introduction port for introducing a process gas into said process chamber;
flow controllers that adjust the flow rates of the process gases; and
a gas flow divider that divides a first process gas into a plurality of gas flows,
wherein at least two pipes for the gas flows divided by the gas flow divider have the first gas introduction port and the second gas introduction port, respectively, and a confluence section for a second process gas to join with the first process gas is provided between the gas flow divider and each of the first gas introduction port and the second gas introduction port.

9. The plasma etching apparatus according to claim 8, the process gas supplied to the first gas introduction port and the process gas supplied to the second gas introduction port differ in flow rate or composition.

10. A plasma etching method using a plasma etching apparatus having:
a process chamber in which a plasma etching is performed on a process target object;
a first gas supply source that supplies a process gas;
a second gas supply source provided separately from said first gas supply source;
a first gas introduction port for introducing the process gas into said process chamber;
a second gas introduction port provided separately from said first process gas introduction port;
a flow controller that adjusts the flow rate of the process gas; and
a gas flow divider that divides the process gas into a plurality of gas flows,
wherein said first gas introduction port and said second gas introduction port are provided substantially in the same plane, and process gasses supplied into said process chamber through said first gas introduction port and said second gas introduction port differ in flow rate or composition.
